(19) United States
(12) Patent Application Publication
(10) Pub. No.: US 2025/0364785 A1
(43) Pub. Date: Nov. 27, 2025

(54) SILICON PHOTONIC DEVICE FOR GENERATING LASER LIGHT

(71) Applicants: COMPOUNDTEK PTE. LTD., Singapore (SG); NANYANG TECHNOLOGICAL UNIVERSITY, Singapore (SG)

(72) Inventors: Jia Xu BRIAN SIA, Singapore (SG); Hong WANG, Singapore (SG); Kian Siong ANG, Singapore (SG)

(21) Appl. No.: 18/691,712

(22) PCT Filed: Feb. 14, 2023
(86) PCT No.: PCT/SG2023/050084

§ 371 Date: Mar. 13, 2024

(51) Int. Cl. H01S 5/14; H01S 5/06; H01S 5/10

(52) U.S. Cl. CPC H01S 5/142; H01S 5/0612; H01S 5/1032

(57) ABSTRACT

The present invention relates to a silicon photonic device (100) for generating laser light. The device (100) comprises a substrate and at least one laser cavity (10, 20, 30) fabricated on the substrate. Each laser cavity (10, 20, 30) is formed with at least one III-V-based gain section (11, 21, 31), at least two microring resonators (MRR) (12, 13, 22, 23, 32, 33) and at least one partial reflector (14, 24, 34). An interposer (15, 25, 35) optically couples each gain section (11, 21, 31) with a corresponding MRR (12, 22, 23). At least one thermo-optic heater is on each MRR (12, 13, 22, 23, 32, 33) for controlling wavelength selectivity of the corresponding MRR (12, 13, 22, 23, 32, 33).

### FIELD OF THE INVENTION

The disclosures made herein relate generally to silicon photonics, and more particularly to a silicon photonic device i.e. multiple waveband-integrated hybrid III-V/Si tunable laser engine, for generating laser light.

### BACKGROUND OF THE INVENTION

Silicon photonics, implementing integrated optics on the silicon-on-insulator (SOI) platform, has attracted significant industrial and academic attention. The main reason being silicon photonics can be manufactured using re-purposed older complementary metal oxide semiconductor (CMOS) nodes which enable manufacturing of silicon-based photonic integrated circuits at low-cost, large-volumes and unprecedented inter- and intra-chip uniformity, unprecedented in the field of integrated optics. Furthermore, silicon photonics has a high index contrast with its cladding (SiO₂). This enables the dense integration of photonic components in a compact form factor, increasing the range of optical functionalities that can be implemented within a small chip area.

However, silicon photonic is beset with a fundamental limitation as a photonic platform in terms of its poor light emission properties. Silicon material has an indirect electronic bandgap. U.S. Pat. No. 10,754,091 B1 discloses an integrated coherent transceiver comprising a tunable laser device with a gain region being coupled with a wavelength tuning section for tuning wavelengths of a laser light outputted from the gain region. However, none of the prior art demonstrates high wavelength-selectivity at the same time longer effective optical path length which will lead to low-noise laser operation, increase in a ratio of optical mode volume.

Hence, there is a need for a silicon photonic device capable of demonstrating high wavelength-selectivity at the same time longer effective optical path length which leads to low-noise laser operation, increase in a ratio of optical mode volume. Furthermore, there is a need for the silicon photonic device capable of reducing nonlinear pressures that can occur in microring resonators (MRR).

### SUMMARY OF THE INVENTION

The present invention relates to a silicon photonic device for generating laser light. The device comprises a substrate and at least one laser cavity fabricated on the substrate, wherein each laser cavity is formed with at least one III-V-based gain section, at least two microring resonators (MRR) and at least one partial reflector. An interposer for optically couples each gain section with a corresponding MRR, wherein at least one thermo-optic heater on each MRR controls wavelength selectivity of the corresponding MRR.

The MRRs of each laser cavity include a first MRR optically coupled to a corresponding second MRR in a serial configuration, such that a light wave exiting an interposer is filtered for wavelength by a corresponding first MRR and then filtered for wavelength by a corresponding second MRR.

In one aspect, each partial reflector is in serial arrangement with the corresponding MRRs, such that a light wave exiting each second MRR enters the corresponding partial reflector. Furthermore, each partial reflector is configured to transmit a fraction of the light wave as a corresponding laser output emission, while a rest of the light wave is reflected back to form a resonating cavity.

Preferably, one of the III-V-based gain sections is configured to operate in at least one of O, C and L waveband. More preferably, each III-V-based gain section is configured to operate in a different waveband.

Preferably, the substrate is a silicon-on-insulator (SOI) platform. More preferably, the SOI platform is a hybrid III-V/silicon platform.

In one aspect, each MRR functions as a single laser longitudinal mode filter.

Since the first MRR and second MRR are arranged in a serial configuration in each laser cavity, each laser cavity realizes high wavelength-selectivity and long effective optical path length which in turn enables low-noise laser operation, increases a ratio of optical mode volume as comparted to the corresponding III-V-based gain section. Furthermore, each partial reflector in serial arrangement with the corresponding MRRs reduces nonlinear pressures that occur in the corresponding MRRs, which in turn avoids losses due to carrier absorption as well as increases noise performance.

The device can be entirely formed as a solid state device and does not require any mechanical moving parts for operation. Each III-V-based gain section is configured to operate in a different waveband and is integrated on to a single silicon photonic chip via hybrid integration, thereby the device is capable of operating in multiple wavebands.

### BRIEF DESCRIPTION OF THE ACCOMPANYING DRAWINGS

The present invention will be fully understood from the detailed description given herein below and the accompanying drawings which are given by way of illustration only, and thus are not limitative of the present invention, wherein:

FIG. 1 shows a schematic diagram of the silicon photonic device, according to an exemplary embodiment of the present invention.

FIG. 2 shows a schematic representation of light propagation through each laser cavity of the device in FIG. 1.

FIG. 3 shows a graphical representation of output optical spectrum of the device in FIG. 1.

FIG. 4 shows a graphical representation of a laser linewidth of the device.

FIGS. 5-7 show graphical representation of output optical power with respect to current, when the device is operated at O-waveband, C-waveband and L-waveband, respectively.

FIG. 8 shows graphical representation of optical spectrum of the device, through its maximum tuning range within the C- and L-wavebands.

FIG. 9 shows a graphical representation of optical spectrum of the device, through its maximum tuning range within the O-waveband.

### DETAILED DESCRIPTION OF THE INVENTION

Detailed description of preferred embodiments of the present invention is disclosed herein. It should be understood, however, that the embodiments are merely exemplary of the present invention, which may be embodied in various forms. Therefore, the details disclosed herein are not to be interpreted as limiting, but merely as the basis for the claims and for teaching one skilled in the art of the invention. The numerical data or ranges used in the specification are not to be construed as limiting. The following detailed description of the preferred embodiments will now be described in accordance with the attached drawings, either individually or in combination.

The present invention overcomes the limitations of the prior art by means of implementing hybrid III-V/Si platform. By exploiting the ability for large-scale integration on the silicon photonics platform, the present invention provides a tunable laser engine capable of operating across multiple wavebands. The present invention allows forming a passive silicon laser cavity with a tuning range of 101 nm at the C to L-waveband, tuning range of 42 nm at the O-waveband, and extraordinary side-mode suppression ratio (SMSR) and total source spontaneous emission ratio of 66 dB and 68 dB respectively. Furthermore, the hybrid III-V/silicon platform allows better quantum noise reduction as compared to solitary III-V counterparts thereof.

The present invention is applicable to cutting-edge applications where significant optical bandwidth (i.e., multi-wavelength multiplexing) and low-noise operation are highly desired. The present invention is capable of realizing a laser optical linewidth of lower than 1 kHz. Furthermore, the present invention is capable of generating a fiber-output power in excess of 10 mW at O, C and L-wavebands.

The present invention provides a hybrid III-V/silicon wavelength-tunable laser cavity including a III-V-based gain section, two or more microring resonators (MRR) for wavelength filtering and a partial reflector. Furthermore, a sequence of implementation of the aforementioned components plays a key role in achieving varied laser performance and is fundamental to the present invention.

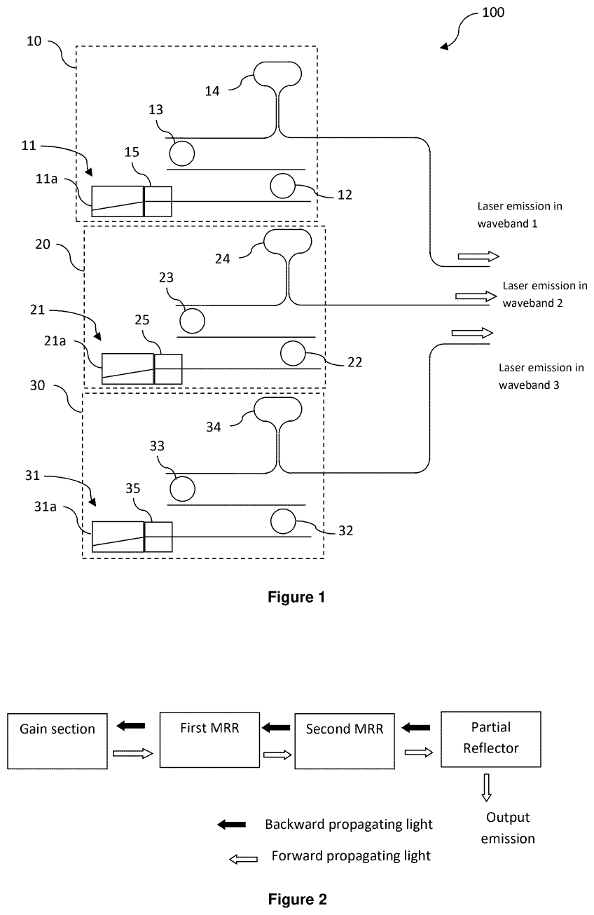

FIG. 1 shows a schematic representation of a silicon photonic device i.e. multiple waveband-integrated hybrid III-V/Si tunable laser engine, in accordance with an exemplary embodiment of the present invention. The device (100) comprises a substrate and at least three laser cavities (10, 20, 30), wherein each laser cavity (10, 20, 30) is formed with a III-V-based gain section (11, 21, 31), two microring resonators (MRR) (12, 13, 22, 23, 32, 33) and a partial reflector (14, 24, 34). Preferably, the substrate is a silicon-on-insulator (SOI) platform. More preferably, the SOI platform is a hybrid III-V/silicon platform.

Each III-V-based gain section (11, 21, 31) is formed with a high reflective (HR) facet (11a, 21a, 31a), wherein another facet of each III-V-based gain section (11, 21, 31) is optically coupled to a corresponding first MRR (12, 22, 32) through an interposer (15, 25, 35), preferably III-V/Si-based interposer. More preferably, a spot size converter (not shown) is optically coupled between each interposer (15, 25, 35) and the corresponding first MRR (12, 22, 32).

Each first MRR (12, 22, 32) is optically coupled to a corresponding second MRR (13, 23, 33), wherein a light wave reflected by each HR face enters the corresponding interposer (15, 25, 35), first MRR (12, 22, 32) and second MRR (13, 23, 33). Each MRR (12, 13, 22, 23, 32, 33) operates as an optical filter to filter wavelength of the light wave, wherein a thermo-optic heater (not shown) is provided on each MRR (12, 13, 22, 23, 32, 33) for controlling wavelength selectivity of the corresponding MRR (12, 13, 22, 23, 32, 33). Preferably, each MRR (12, 13, 22, 23, 32, 33) functions as a single laser longitudinal mode filter. The light wave exiting each second MRR (13, 23, 33) enters the corresponding partial reflector (14, 24, 34) that is configured to transmit a fraction of the light wave as a corresponding laser output emission, while a rest of the light wave is reflected back to form a resonating cavity. It is to be understood that optical coupling of the components (III-V-based gain sections (11, 21, 31), MRRs (12, 13, 22, 23, 32, 33), interposers (15, 25, 35) and partial reflectors (14, 24, 34)) of each laser cavity (10, 20, 30) is achieved by means of direct coupling or through a light guide such as optical fiber, or any other convention means capable of coupling light waves between two components.

Since the first MRR (12, 22, 32) and second MRR (13, 23, 33) are arranged in a serial configuration in each laser cavity (10, 20, 30), each laser cavity (10, 20, 30) realizes high wavelength-selectivity and long effective optical path length which in turn enables low-noise laser operation, increases a ratio of optical mode volume as comparted to the corresponding III-V-based gain section (11, 21, 31). Furthermore, each partial reflector (14, 24, 34) is in serial arrangement with the corresponding MRRs (12, 13, 22, 23, 32, 33), and thereby reduces nonlinear pressures that occur in the corresponding MRRs (12, 13, 22, 23, 32, 33), which in turn avoids losses due to carrier absorption as well as increases noise performance.

The device is entirely formed as a solid state device and does not require any mechanical moving parts for operation. At least one of the III-V-based gain sections (11, 21, 31) are configured to operate in an O, C or L-waveband. Preferably, each III-V-based gain section (11, 21, 31) is configured to operate in a different waveband, and is integrated on to a single silicon photonic chip via hybrid integration, thereby the device (100) is capable of operating in multiple wavebands.

According to requirement, the number of gain sections integrated on to the chip and operating wavebands can be configured. Length of each gain section (11, 21, 31) is 1 mm. Footprint of the multiple-gain silicon photonic laser cavity is 14.7×5 mm² and can be reduced in future iterations through less conservative waveguide routing. With the compact form factor as mentioned, the device (100) is capable of lasing across all three wavebands (O, C, L).

The device is operable in a wavelength-tuning range of 101 nm at the C to L-waveband and at 42 nm at the O-waveband. Ultra-high laser SMSR of 70 dB is obtained through controlling the selectivity of the MRRs (12, 13, 22, 23, 32, 33). Output power of the device (100) in each waveband is in excess of 10 mW. Low-noise laser operation is achieved with a laser optical linewidth lower than 1 kHz.

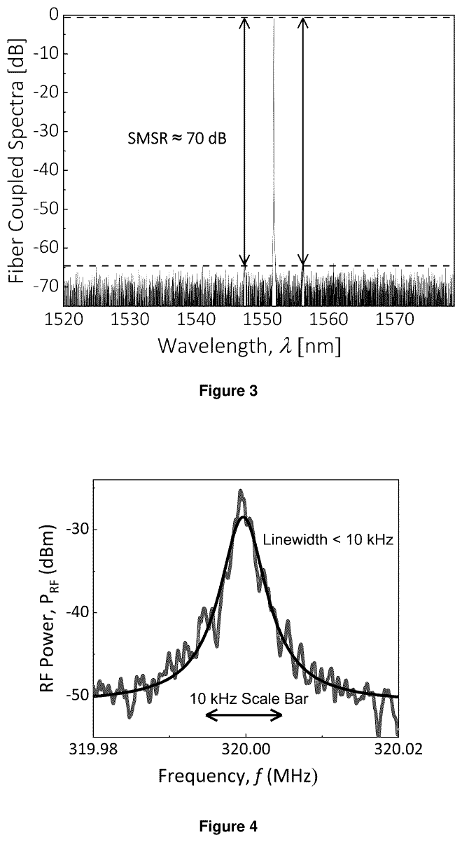

Since each first MRR (12, 22, 32) are in serial arrangement with the corresponding second MRR (13. 23. 33), the light wave in each laser cavity (11, 21, 32) has to propagate through the corresponding first MRR (12, 22, 32) before moving on to the corresponding second MRR (13, 23, 33), as shown in FIG. 2. This leads to increased wavelength selectivity as indicated by the superior SMSR and of 70 dB respectively, as shown in the FIG. 3.

The forward propagating lightwave is filtered through the series implementation of the first MRRs (12, 22, 32) and the corresponding second MRRs (13, 23, 33), while the backward propagating lightwave reflected by the partial reflectors (14, 24, 34) passes through the series implementation of the second MRRs (13, 23, 33) and the corresponding first MRRs (12, 22, 32), as shown in FIG. 2. Thus, effective optical path length of each laser cavity (10, 20, 30) is increased, thereby increasing an optical mode volume in each passive silicon photonic wavelength-selective laser cavity in contrast to the III-V-based gain section (11, 21, 31). This enables laser low-noise operation. The laser engine optical laser linewidth is measured to be lower than 10 kHz. Furthermore, as all the lightwave passes through the series implemented MRRs once in the forward direction and 1-R of the lightwave power in the backward direction, the wavelength selectivity of the filter is increased. This is shown by the high laser SMSR of 70 dB respectively.

Since the partial reflectors (14, 24, 34) are implemented after the series implemented MRRs (12, 13, 22, 23, 32, 33), as shown in FIG. 2, MRR cavity power intensity is reduced, which in turn reduces nonlinear pressure on the MRRs, and thus leading to minimize losses and laser noise. The complete functionality of the present invention is explained in detail in reference to FIG. 1 in the forthcoming paragraphs.

When an injection current is inputted, the III-V gain section (11, 21, 31) of each laser cavity (10, 20, 30) generates a light wave which is reflected by the corresponding HR facet (11a, 21a, 31a) and exits the corresponding opposite facet to enter the interposer (15, 25, 35) that is optically coupled to the III-V gain section (11, 21, 31). The light wave propagating through each interposer (15, 25, 35) enters the corresponding first MRR (12, 22, 32), wherein the light wave is filtered for wavelength according to the selectivity of the first MRR (12, 22, 32) which is controlled by the corresponding thermos-couple heater. The light wave from each first MRR (12, 22, 32) enters the corresponding second MRR (12, 22, 32), wherein the light wave is further filtered for wavelength according to the selectivity of the second MRR (13, 23, 33) which is controlled by the corresponding thermos-couple heater. The wavelength filtered light wave from each second MRR (13, 23, 33) enters the corresponding partial reflector (14, 24, 34), wherein a fraction of the light wave exits the device (100) at an output port (not shown) as a corresponding laser output emission, while a rest of the light wave is reflected back to form a resonating cavity.

Each laser cavity (10, 20, 30) includes the two MRRs (11, 12, 21, 22, 31, 32), with a radius of ˜20 μm, implemented in a series configuration to enable strong wavelength-selectivity, which improves the SMSR and noise characteristics of the laser cavity, increases effective optical path length of the laser cavity and increases a ratio of optical mode volume in the laser cavity in contrast to the corresponding III-V-based gain section. The power coupling coefficient between the MRRs and the straight waveguide in the wavelength-tunable laser cavity is ˜10%.

Wavelength-tunable characteristics of the device (100) are obtained at a tunable range of 101 nm at the C to L-waveband, and 42 nm at the O-waveband. The bias current (I_{bias}) current level of the O, C, and L-waveband are 85 mA, 50 mA and 70 mA respectively. Benefiting from the present invention, high SMSR of 70 dB can be obtained. The present invention demonstrates low-noise operation with a laser optical linewidth of lower than 1 kHz and −145 dB/Hz respectively. Fiber-coupled output power in excess of 10 mW is measured across O, C and L-wavebands.

FIG. 3 shows a measured output optical spectrum obtained from simulation of the device (100), in which lasing wavelength of the laser is determined through a voltage applied to the thermo-optic heater on each MRR. The output of the laser unit was coupled through a lensed fiber, connected to an optical spectrum analyser for measurement of the spectrum.

FIG. 4 indicates a laser linewidth measured using a recirculating fiber loop integrated delayed self-heterodyne interferometer measurement technique where a lightwave from a laser unit has circulated 4 rounds in a fiber loop. Length of the fiber loop is set as 35 km. Delay length corresponding to the result is 140 km. Optical linewidth of the laser unit corresponds to half of the full width half maximum of a beat signal, wherein the optical linewidth of the laser unit is measured to be significantly lower than 10 kHz.

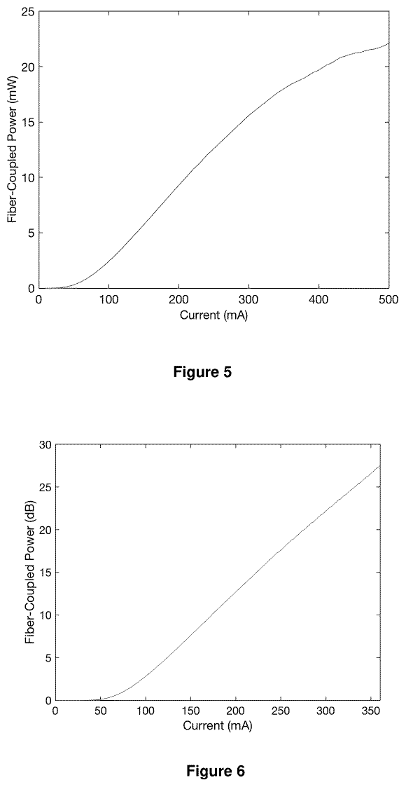

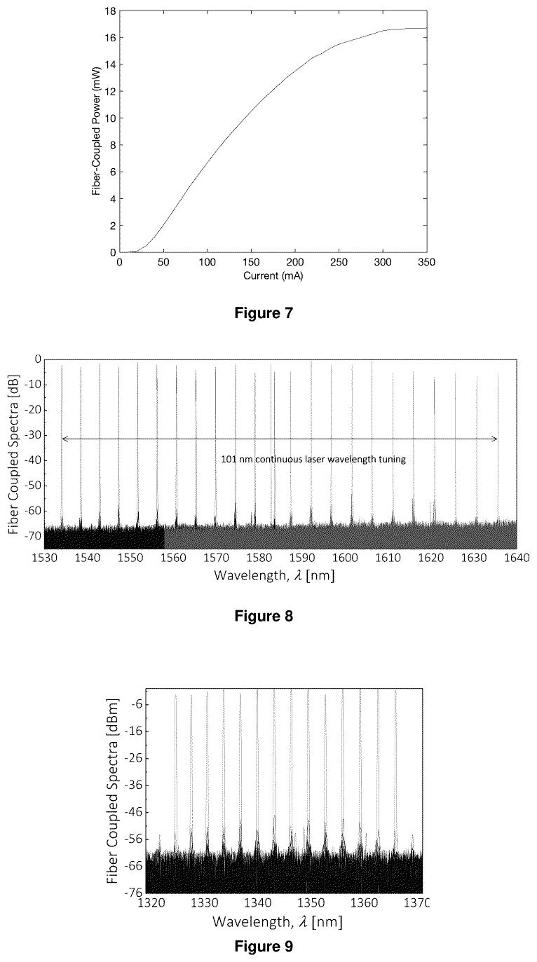

FIG. 5 indicates the output optical power vs laser current of the laser unit, when operating at O-waveband. Similarly, FIGS. 6 and 7 indicate the output optical power vs laser current of the laser unit, when operating at C-waveband and L-waveband, respectively. In each of the above cases, the optical power is coupled directly into an opening of a photodiode for conversion.

FIG. 8 shows an optical spectrum of the laser unit, through its maximum tuning range within the C- and L-wavebands, achieved through control of voltage applied to thermo-optic heaters on MRRs. The output power of the laser unit was coupled through a lensed fiber connected to an optical spectrum analyser for measurement. Similarly, FIG. 9 shows an optical spectrum of the laser unit, through its maximum tuning range within the O-waveband, achieved through the control of voltage applied to the thermo-optic heaters on the MRRs. The output power of the laser unit was coupled through a lensed fiber, connected to an optical spectrum analyser for measurement.

Each individual waveband is unique in terms of the applications thereof. For example, the O, C, and L wavebands enables optical communications. On the other hand, the 1.65 μm wavelength region enables spectroscopy of methane (CH₄). Even though the above embodiments show the present invention including 3 laser cavities, it is to be understood that the number of laser cavities in the device can be varied according to the waveband-specific application. Commercial applications of the present invention includes not limited to instrumentation, optical communications, Light Detection and Ranging (LIDAR) and optical spectroscopy.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises”, “comprising”, “including” and “having” are inclusive and therefore specify the presence of stated features, integers, steps, operations, elements and/or components, but do not preclude the presence or addition of one or more other features, integers, steps, operations, elements, components and/or groups thereof.

The method steps, processes and operations described herein are not to be construed as necessarily requiring their performance in the particular order discussed or illustrated, unless specifically identified as an order of performance. It is also to be understood that additional or alternative steps may be employed. The use of the expression “at least” or “at least one” suggests the use of one or more elements, as the use may be in one of the embodiments to achieve one or more of the desired objects or results.

1. A silicon photonic device (100) for generating laser light, comprises:
i. a substrate;
ii. at least one laser cavity (10, 20, 30) fabricated on the substrate, wherein each laser cavity (10, 20, 30) is formed with at least one III-V-based gain section (11, 21, 31), at least two microring resonators (MRR) (12, 13, 22, 23, 32, 33) and at least one partial reflector (14, 24, 34);
iii. an interposer (15, 25, 35) for optically coupling each gain section (11, 21, 31) with a corresponding MRR (12, 22, 23); and
iv. at least one thermo-optic heater on each MRR (12, 13, 22, 23, 32, 33) for controlling wavelength selectivity of the corresponding MRR (12, 13, 22, 23, 32, 33),
characterized in that said MRRs (12, 13, 22, 23, 32, 33) of each laser cavity (10, 20, 30) include a first MRR (12, 22, 32) optically coupled to a corresponding second MRR (13, 23, 33) in a serial configuration, such that a light wave exiting an interposer (15, 25, 35) is filtered for wavelength by a corresponding first MRR (12, 22, 32) and then filtered for wavelength by a corresponding second MRR (13, 23, 33).

2. The device (100) as claimed in claim 1, wherein each partial reflector (14, 24, 34) is in serial arrangement with the corresponding MRRs (12, 13, 22, 23, 32, 33), such that a light wave exiting each second MRR (13, 23, 33) enters the corresponding partial reflector (14, 24, 34).

3. The device (100) as claimed in claim 2, wherein each partial reflector (14, 24, 34) is configured to transmit a fraction of the light wave as a corresponding laser output emission, while a rest of the light wave is reflected back to form a resonating cavity.

4. The device (100) as claimed in claim 1, wherein one of said III-V-based gain sections (11, 21, 31) is configured to operate in at least one of O, C and L waveband.

5. The device (100) as claimed in claim 1, wherein each III-V-based gain section (11, 21, 31) is configured to operate in a different waveband.

6. The device (100) as claimed in claim 1, wherein said substrate is a silicon-on-insulator (SOI) platform.

7. The device (100) as claimed in claim 6, wherein said SOI platform is a hybrid III-V/silicon platform.

8. The device (100) as claimed in claim 1, wherein each MRR (12, 13, 22, 23, 32, 33) functions as a single laser longitudinal mode filter
